(19) United States
(12) Patent Application Publication
(10) Pub. No.: US 2006/0150047 A1
(43) Pub. Date: Jul. 6, 2006

(54) Apparatus and method for generating a high-frequency signal

(76) Inventors: Wolfgang Nikutta, Munich (DE); Thomas Nirmaier, Munich (DE)

Correspondence Address: SLATER & MATSIL LLP, 17950 PRESTON ROAD, SUITE 1000, DALLAS, TX, 75252, US

(21) Appl. No.: 11/027,918

(22) Filed: Dec. 30, 2004

(51) Int. Cl. G01R 31/28; G06F 11/00

(52) U.S. Cl. 714/742

(57) ABSTRACT

An apparatus for generating an output signal having a higher frequency than a first signal received from a first external connector of a test equipment associated to a first channel and a second signal received on a second external connector of the test equipment associated to a second channel, having a first connector adapted to be connected to said first external connector, and adapted to receive the first signal, a second connector adapted to be connected to said second external connector, and adapted to receive the second signal, wherein the first and second signals are out of phase, an output to be connected to the device under test, and a passive circuit for combining the signals received at said first and second connector into the output signal and for providing said output signal to said output.

### BACKGROUND OF THE INVENTION

1. Field of the Invention

The present invention refers to an apparatus and a method for generating an output signal having a higher frequency than a received input signal. In particular, the apparatus and method can be used in combination with test equipment for the frequency doubling, triplicating or n-times multiplication of digital signals used for testing a device.

2. Description of the Related Art

Semiconductor automated test equipment like the HP 83000 (™) from Hewlett Packard or the EXA 3000 (™) and the Sapphire (™) from Credence is widely used in the semiconductor industry for the design analysis and the characterization of devices and during production test. In digital ATEs (ATE; ATE=automated test equipment) the test system offers a number of channels with programmable input low VIL (VIL; VIL=Voltage Input Low) and input high level VIH (VIH; VIH=Voltage Input High) and an underlying timing of these voltage levels. Usually each digital input pin of a device under test is connected to one of the testers' channels through a load board and the test will provide the device under test (DUT; DUT=device under test) with the levels and timings for the required test.

Each test system has a specific upper limit for the minimum period, i.e., maximum frequency and data rate, e.g., 500 MHz or 1 Gbit/s. As memory and logic devices become faster, they quickly surpass the uppermost frequency range of ATEs. Expensive new systems have to be purchased, which form a large part of the total cost for semiconductor testing.

Up to now this problem has been solved by the purchase or rental of ATEs with a larger uppermost data rate.

For periodic signals, like clock signals, a frequency multiplication can also be achieved by delay-locked loops and phase-locked loops as it is described in “CMOS Circuit Design, Layout and Simulation” by Baker, Li, Boyce, IEEE Press 1997 or in http://en.wikipedia.org/wiki/Phase-locked_loop. These complex circuits are not only large and difficult to implement on a load board, but they also need a certain time to settle. This solution is impossible for command or data signals.

### SUMMARY OF THE INVENTION

It is the object of the present invention to provide an apparatus and a method for generating an output signal which allows a cost-effective testing of a device.

In accordance with a first aspect, the present invention provides an apparatus for generating an output signal having a higher frequency than a first signal received from a first external connector of a test equipment associated to a first channel and a second signal received on a second external connector of the test equipment associated to a second channel, having a first connector adapted to be connected to the first external connector, and adapted to receive the first signal, a second connector adapted to be connected to the second external connector, and adapted to receive the second signal, wherein the first and second signals are phase shifted with respect to each other, an output to be connected to the device under test, and a path circuit for combining the signals received at that first and second connector into the output signal and for providing the output signal to the output.

In accordance with a second aspect, the present invention provides a signal generator, having an apparatus for generating an output signal, a first driver for providing the first signal, and a second driver for providing the second signal.

In accordance with a third aspect, the present invention provides a method for generating an output signal having a higher frequency than a first signal received from a test equipment associated to a first channel and a second signal received from the test equipment associated to a second channel, having the steps of receiving the first signal on a first input, receiving a second signal on a second input, wherein the first and second signals are phase shifted with respect to each other, combining the signals received at the first and second input by using a passive circuit, into an output signal, and providing the output signal to an output, adapted to be connected to a device under test.

In accordance with a fourth aspect, the present invention provides a usage of a passive circuit comprising a first input, a second input and an output, the output providing an output signal being a combination of input signals applied to the first and second input and having a higher frequency than the input signals for increasing the frequency of signals provided on a first and a second channel of a test equipment by connecting the first input to the first channel and the second input to the second channel.

According to the present invention the frequency limit of test equipment is surpassed by joining two or more tester channels with a properly designed network on a load board and an adequate timing of the test channels. The present invention allows frequency multiplication for digital signals with resistor networks. It is an advantage of the present invention that the bandwidth of any digital signal, not only the bandwidth of periodic signals, can be increased.

The proposed solution has the potential to test devices that require a very high data rate with slow automated test equipment, which is not able to generate such high frequency signals. The inventive approach allows a re-use of test equipment for the test of newly-developed high-speed devices by the usage of a passive circuit. Thus, it is not necessary to purchase new test equipment or any new production cycle. The proposed apparatus for generating a high-frequency signal is easy to implement with passive elements like resistors and avoids the use of large and expensive active components.

According to an embodiment, frequency multiplication is achieved by the addition of test channels with an appropriate timing through a resistor network. Signal integrity is one of the basic problems in high bandwidth communications. If a signal, traveling through a transmission line to the receiver, passes through an impedance discontinuity, part of the signal will be reflected and causes signal degradation as described in “High-speed signal propagation” by Johnson, Graham, Prentice-Hall, 2003 or in http://www.ece.umd.edu/courses/enee759h.S2003/references/sign aling_tutorial.pdf. This degradation can lead to bit errors. The proposed resistor network avoids impedance discontinuities and thereby bit errors.

### BRIEF DESCRIPTION OF THE DRAWINGS

These and other objects and features of the present invention will become clear from the following description taken in conjunction with the accompanying drawing, in which

FIG. 1a is a schematic view of an apparatus for generating an output signal according to an embodiment of the present invention;

FIG. 1b is a schematic view of an apparatus for generating an output signal according to a further embodiment of the present invention;

FIG. 2 is a timing diagram showing the timing and level of signals according to an embodiment of the present invention;

FIG. 3 is a timing diagram which shows the timing and level of signals according to a further embodiment of the present invention;

FIG. 4 is a table showing logical levels for input signals according to an embodiment of the present invention;

FIG. 5 is a flowchart describing a method for generating an output signal according to an embodiment of the present invention;

FIG. 6 is a schematic view of a test apparatus according to an embodiment of the present invention; and

FIG. 7 is a timing diagram which shows the timings and levels of signals according to a further embodiment of present invention.

The following list of reference symbols can be used in conjunction with the figures.

100 apparatus for generating an output signal

102, 102a first channel

104, 104a second channel

112, 112a first signal

114, 114a second signal

116, 116a output signal

106 device under test

122 common connection point

124, 126, 128 resistors

315 third input signal

540 step of calculating

542 step of generating

544 step of merging

546 step of providing

601 test equipment

630 calculation unit

712 first signal

714 second signal

715 third signal

716 output signal

716′ required signal

### DESCRIPTION OF THE PREFERRED EMBODIMENTS

In the following description of the preferred embodiments of the present invention same or similar reference numbers are used for similar elements shown in different figures, wherein a repeated description of these elements is omitted.

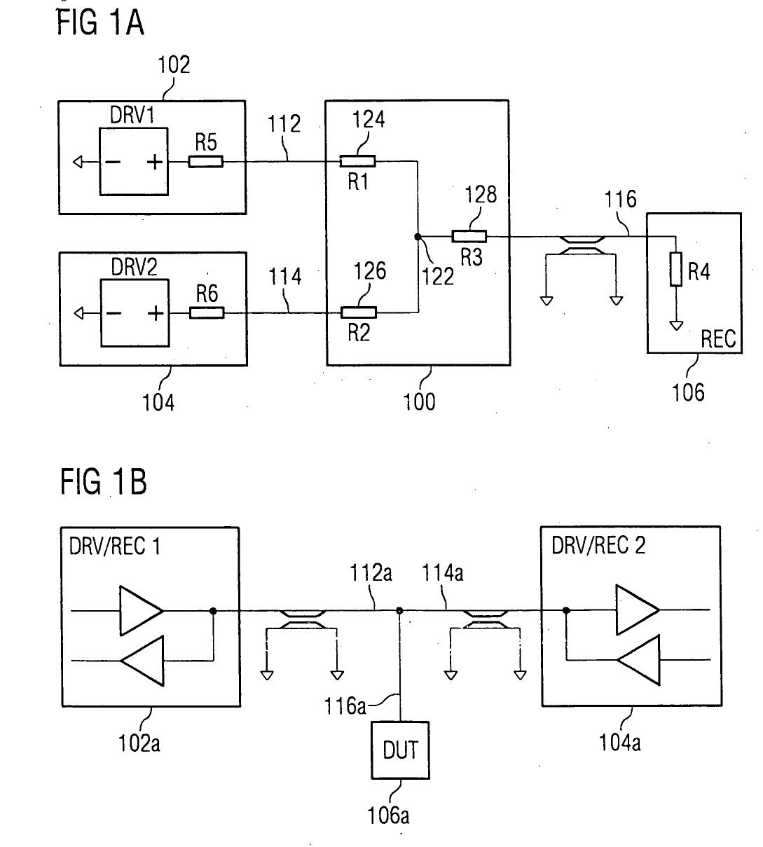

FIG. 1a shows a schematic view of an apparatus 100 for generating an output signal according to an embodiment of the present invention. Besides the apparatus 100 for generating an output signal, FIG. 1a shows a first channel 102 and a second channel 104 of an automated test equipment (the test equipment is not shown in FIG. 1a) and a device under test 106.

The first test channel 102 comprises a driver DRV1 and a driver impedance R5. The first channel 102 is configured to generate a first signal 112, which is received by the apparatus 100 on a first external connector. Accordingly, the second channel 104 comprises a second driver DRV2 and a driver impedance R6 and is configured to generate a second signal 114 which is received by the apparatus 100 on a second connector. The apparatus 100 is configured to combine the input signals 112, 114 and to generate and provide an output signal 116 to the device under test 106. In FIG. 1a, the device under test is represented by a receiver comprising a termination resistance R4 which is connected to ground. For the present invention it is not necessary that the device under test DUT comprises the termination resistance R4. A signal line for connecting the apparatus 100 with the device under test can comprise a coupling element which avoids signal reflections.

According to this embodiment, the apparatus 100 comprises a first resistor R1 124, a second resistor R2 126 and a third resistor R3 128. The first, second and third resistors 124, 126, 128 comprise a common connection point 122, wherein the common connection point 122 is adapted to combine the first and second signals 112, 114 in order to generate the output signal 116. The first resistor 124 connects the first connector of the apparatus 100 with the connection point 122, the second resistor 126 connects the second connector of the apparatus 100 with the connection point 122, and the third resistor connects the output of the apparatus 100 with the connection point 122. Alternatively any other arrangement of resistors suitable for combining the signals 112, 114 can be chosen.

According to this embodiment, frequency doubling is achieved by joining the two channels 102, 104 with a power splitter which is realized by the resistors 124, 126, 128 of the apparatus 100. Frequency doubling means that the output signal 116 of the apparatus 100 has twice as many edges as the input signals 112, 114. According to this embodiment, the impedance of the whole circuit is 50 Ω. Alternatively, the apparatus 100 can be adapted to any other impedance. In order to avoid impedance discontinuities, the resistor network of the apparatus 100 is carefully designed and the impedance of the testers' drivers is taken into account. According to this embodiment, the first, second and third resistors 124, 126, 128 comprise a resistance of 16.6 Ω. The resistors R5, R6 of the channels of the test equipment 102, 104, as well as the resistor R4 of the device under test 106 comprise a resistance of 50 Ω.

The schematic of the apparatus 100 shown in FIG. 1a is a generic example. It can be replaced by any kind of resistor networks that provide the required impedance of 50 Ω in this embodiment.

Alternatively the setup of the apparatus 100 can also be replaced by a network with two separated transmission lines. According to such an embodiment, shown in FIG. 1b, the required waveform at the device under test can be achieved by a fly-by of adequately timed signals from separated tester channels 102a, 104a. Two separated transmission lines means that the two tester channels 102a, 104a are lead to the DUT by way of two separated transmission lines 112a, 114a. The two separated transmission lines 112a, 114a are brought together as close to the DUT as possible. The signals of the two or alternatively of a plurality of tester channels superimpose in a transmission line 116a. In particular “fly-by” means that the signal of the driver DRV1 of the first channel 102a is not terminated by the DUT 106a, but “flys” past the DUT 106a to the receiver REC2 of the second channel 104a and is terminated in the receiver REC2.

The resistor network of the apparatus 100 functions as a power splitter. This means that there is a voltage drop at the resistors of the apparatus 100. If the first signal 112 of the first channel is at a high voltage level, there is a voltage drop along the first resistor 124 and the third resistor 128 additional to a voltage drop at the resistor R5 of the first channel 102 and the resistor R4 of the device under test 106. If the first channel 102 drives a high voltage level and the second channel 104 drives a low voltage level, there is an additional voltage drop from the connection point 122 along the second resistor 126 of the apparatus 100 and the resistor R6 of the second channel 104.

An output signal 116 with a double frequency or half cycle time tck, when compared to the input signals 112, 114 is achieved by setting both drivers DRV1, DRV2 on the two channels 102, 104 to 75% duty cycle and setting a delay of tck/2 in between the signals.

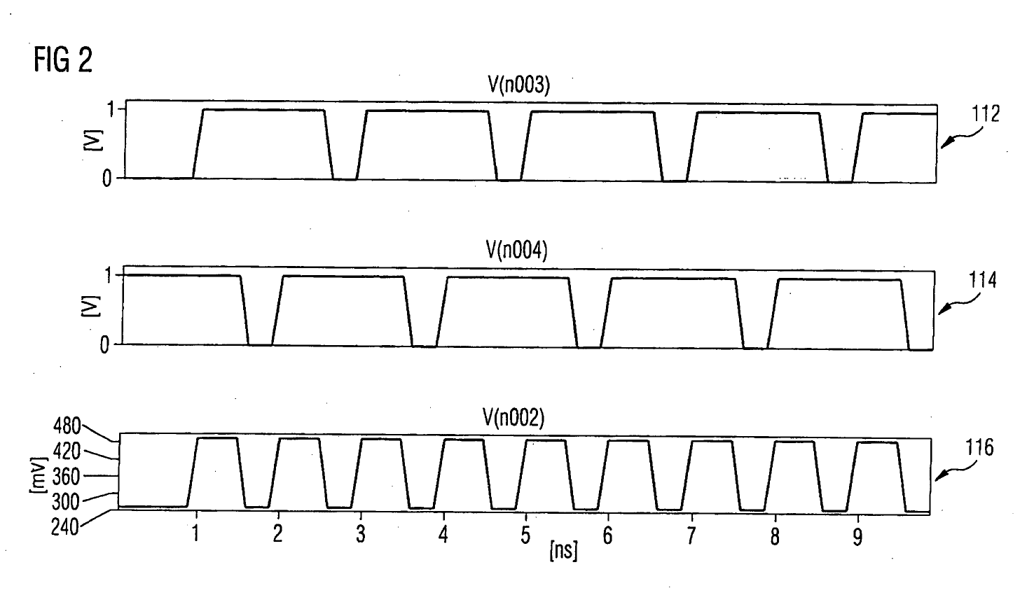

FIG. 2 shows a timing configuration of the first and second input signals 112, 114 which results in an output signal 116 with a double frequency when compared to the input signals 112, 114. FIG. 2 shows the generation of a 1 GHz clock signal 116 out of two 500 MHz input signals 112, 114. The first and second input signals 112, 114 both have a duty cycle of 75%. The second signal 114 is delayed by a quarter cycle time when compared to the first signal 112. The first and second signals 112, 114 both have a low voltage level at 0 V and a high voltage level at 1 V. Due to the apparatus 100 for generating an output signal, the output signal 116 has a low voltage level of 240 mV and a high voltage level of 480 mV. Although reference has been made to particular voltage levels in this embodiment, it is clear that any other voltage levels can be chosen, as long as the voltage levels of the drivers are corrected corresponding to the given resistor network and the required levels at the DUT.

Frequency triplication can be achieved by three channels and a 3-way power splitter. In the embodiment shown in FIG. 1a, a frequency triplication can be achieved by further incorporating a third channel in the apparatus for generating an output signal which then comprises a third connector for receiving a third input signal from the third channel and a further resistor for connecting the third input signal to the connecting point 122. The advantage of a frequency triplication is that the tester channels can be driven with a 50% duty cycle, i.e., there is a larger margin with large rise-and-fall times for the resulting waveform.

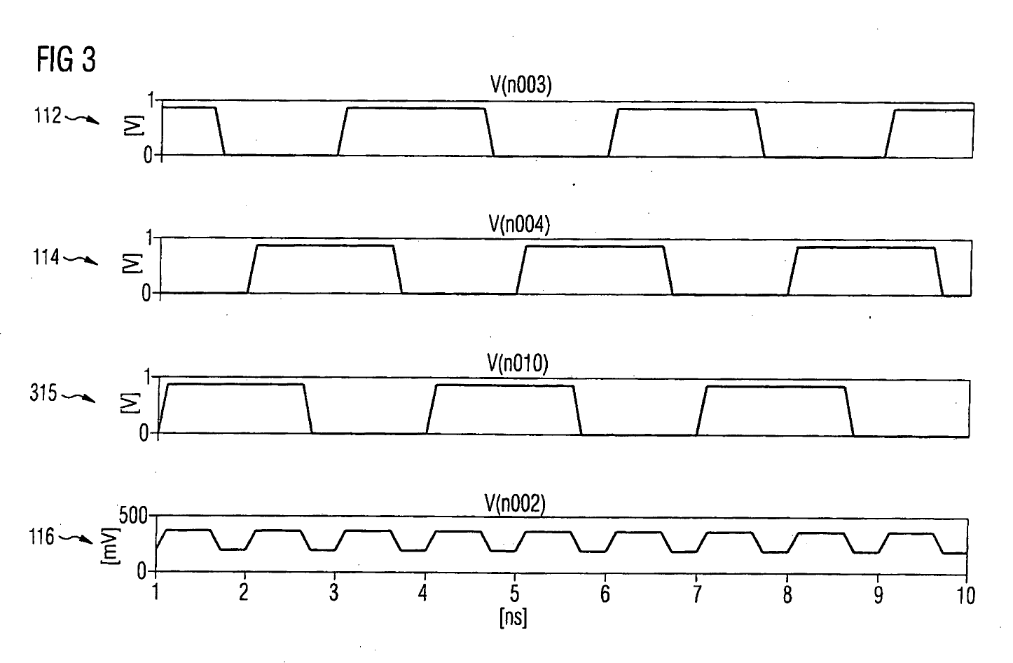

FIG. 3 shows corresponding waveforms for a setup with three tester channels 112, 114, 315 to synthesize a 1 GHz clock output signal 116 out of three 333 MHz signals 112, 114, 315. When compared to the first signal 112, the second signal 114 is delayed by ⅔ tck and the third signal 315 is delayed by ⅓ tck.

The timing of the input signals 112, 114, 315 can be chosen such that a most relaxed timing for the drivers of the channels can be achieved for achieving a logical high level or a logical low level at the output signal 116.

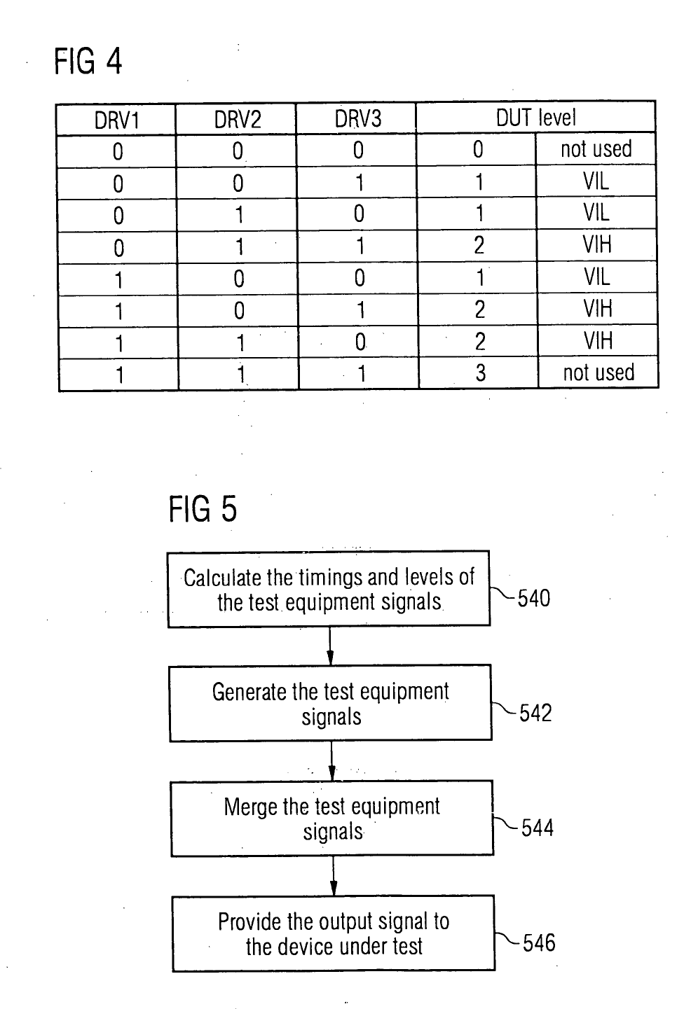

FIG. 4 shows possible combinations of three input signals from the drivers DRV1, DRV2, DRV3, which can be used for a frequency triplication. Further, possible output levels (DUT levels) provided to the device under test are shown. The most relaxed timing for the drivers can be achieved by using DUT level 1 for the low voltage level VIL and DUT level 2 for the high voltage level VIH. To drive the DUT from VIH to VIL only one of the tester drivers DRV1, DRV2, DRV3 has to switch. In a next cycle another one switches and so on.

In the previous embodiments, a frequency doubling and a frequency triplication has been described. In the following, the general rules to achieve an n-time frequency multiplication with a resistive network of n independent channels with a lower bandwidth than the bandwidth of the desired output signal are described. FIG. 5 shows a schematic flowchart of a method for generating an output signal having a higher frequency than input signals. In a first step 540, the timings and levels of the test equipment signals are calculated. The timing of the test equipment signals depends on the number of channels used and on the required factor of the frequency multiplication. For an n-time frequency multiplication there are 2ⁿ (VIH, VIL) combinations for n drivers and the same number of levels, when combined with a resistor network. Just two voltage levels as VIH and VIL at the device under test are needed. By using the same levels VIH, VIL for all tester drivers, the number of possible levels at the device under test reduces to n+1, but there are still 2ⁿ combinations of (VIH, VIL) to achieve same. Out of all these combinations the ones are chosen that lead to the most relaxed timing for the drivers. These are the ones where the same level appears most often, as can be seen in the embodiment described in FIG. 4. In the general case of n-times multiplication the combinations for the VIH and the VIL levels should be chosen such that one half of the drivers drive VIH and the other half drive VIL. For example, the timing can be determined such that half the signals plus 1 are at a high level for driving a high output signal VIH and half the signals plus 1 are at a low level for driving a low output signal VIL.

For odd n the duty cycle of the driven signals can be chosen to be 50%. For an even n a duty cycle larger than 50%, e.g., 75%, cannot be avoided.

The required levels of the test equipment signals depend on the apparatus for generating an output signal. The signal levels at the device under test are reduced by the resistor network in the apparatus with respect to driving directly without a resistor network. Nevertheless, this reduction can be compensated by driving larger signals from the testers' driver to achieve the required signal level at the device under test. Levels can also be shifted arbitrarily to higher or lower VIH and VIL by shifting the levels of the drivers, as long as the swing of all drivers is equal.

The calculation 540 can be done automatically in a separate block for calculating which can be part of the test equipment or be a separate block. The calculation block can allow a user to select a multiplication factor that defines a relationship between the clock periods of the input signals and the clock period of the output signal, and allow the user to select a required voltage level at the device under test.

The block for calculating can be configured to calculate the timing of the first and second signals dependent on the selected multiplication factor. Alternatively, the calculation can be done by the user and afterwards, the user performs the necessary selections, i.e., selects the appropriate timings, delays and levels of the different channels of the test equipment being used for generating the input signals for the apparatus for generating an output signal.

In a next step 542, the test equipment signals, which are used as an input for the apparatus for generating an output signal are generated. Typically, the generation is done by a test equipment which provides appropriate channels.

Further, in a following step 544, the test equipment signals are merged by way of an apparatus for generating an output signal. The signals can be merged by any kind of combination like a superposition, an overlaying or mixing of the input signals. In a following step for providing 546, the output signal which is generated by the apparatus for generating an output signal is provided to the device under test.

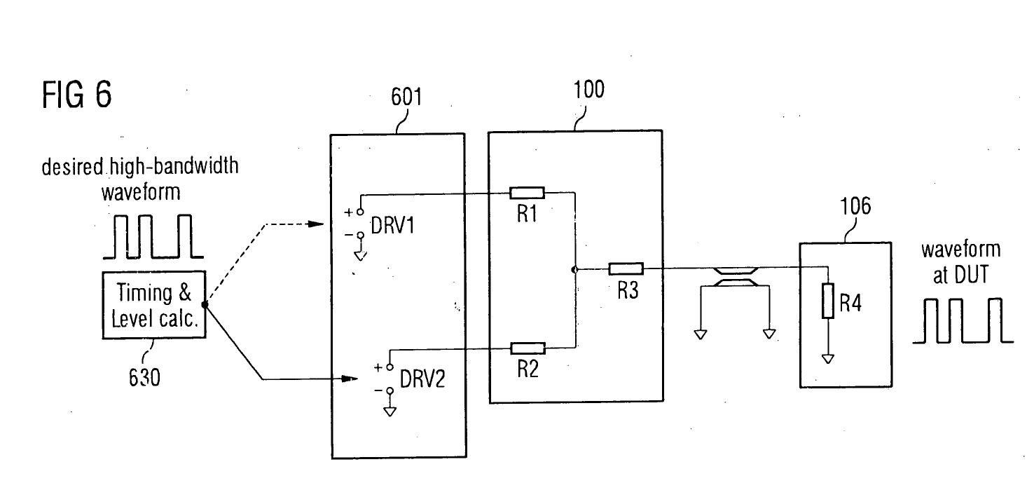

FIG. 6 shows a schematic view of a further embodiment of an apparatus 100 for generating an output signal in combination with a test equipment. The apparatus 100 for generating an output signal is connected to a test equipment 601 comprising a first and a second driver DRV1, DRV2 for providing a first and second input signal to the apparatus 100. The apparatus 100, which comprises a first, a second and a third resistor as described in FIG. 1a, provides an output signal to a device under test 106. According to this embodiment, the drivers DRV1, DRV2 are controlled by a calculation block or control unit 630, which is configured to calculate the timing and levels of the signals generated by the test equipment 601 in order to achieve a desired high-bandwidth waveform at the device under test. The automated test equipment 601 comprises two or more independent channels. The control unit 630 can be adapted to control the first and second drivers such that a timing of the first and second signals is such that the clock period of the output signal is a multiple of the frequency of the first and second signals.

The resistor network formed by the resistors R1, R2, R3 of the apparatus 100 is configured to merge the channels of the test equipment 601 and to provide the device under test with the desired waveforms.

The resistor network of the apparatus 100 has to provide the common impedance environment with an impedance Z for all transmitted signals. For a star-type power-splitter as it is shown in FIG. 6, this means that the resistors R1, R2, R3 comprise values of Z/(n+1). Other configurations of the resistor network are possible too, e.g., to join four channels by first joining channel 1 and channel 2, joining channel 3 and channel 4, and then joining these two again in a tree-like manner.

According to a further embodiment, the apparatus comprises a delay line for delaying one or a plurality of the input signals to achieve the required timing. Alternatively the apparatus can receive only a single input signal and derives the further required signals from the one input signal by using the delay line.

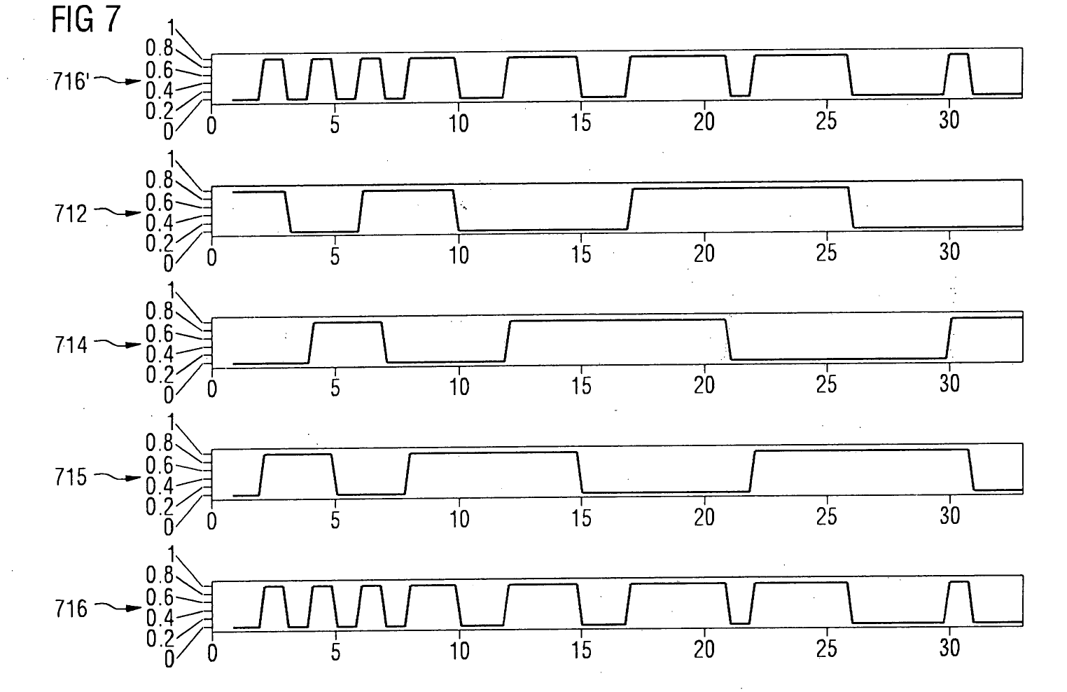

FIG. 7 shows waveforms for a setup with three tester channels. The signals 712, 714, 715 of the three tester channels are combined to a merged signal 716, which corresponds to a required signal 716′ at the DUT. The embodiment shows that the inventive approach is usable for any digital signals like command signals or data signals. A periodic signal like a clock can be generated by a superposition of phase-shifted copies of a slower clock. To generate more complex signals a “calculation block” can be used to calculate the necessary signals 712, 714, 715. In FIG. 7 the signal 716′ is the required signal at the DUT, the signals 712, 714, 715 are signals of three driver channels wherein the edges are placed according to an algorithm to generate the required signal 716 that is a result of a merging of the signals 712, 714, 715 by way of a suitable resistor network. The voltage levels shown in FIG. 7 are not adjusted, yet. The level calculation depends on the DUT levels and the resistor setup.

The edge placing on the signals 712, 714, 715 is an important step in the calculation of the signals 712, 714, 715. The larger the number of edges per time, the higher is the bandwidth of the required signal 716.

Although the embodiments describe single ended signals, it is obvious that the described method for frequency multiplication can be used for differential signals and for current mode signals.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following patent claims be interpreted as including all such alterations, permutations, and equivalents that fall within the true spirit and scope of the present invention.

What is claimed is:

1. Apparatus for generating an output signal having a higher frequency than a first signal received from a first external connector of a test equipment associated to a first channel and a second signal received on a second external connector of the test equipment associated to a second channel, comprising:
a first connector adapted to be connected to said first external connector, and adapted to receive the first signal;
a second connector adapted to be connected to said second external connector, and adapted to receive the second signal, wherein the first and second signals are phase shifted with respect to each other;
an output to be connected to a device under test; and
a passive circuit for combining the signals received at said first and second connector into the output signal and for providing said output signal to said output.

2. The apparatus according to claim 1, wherein the passive circuit is a resistor network, being adapted to provide a common impedance for the signals received from the test equipment and for the output signal.

3. The apparatus according to claim 2, wherein the resistor network comprises a first resistor for connecting the first connector to a common connection point;
a second resistor for connecting the second connector to the common connection point; and
a third resistor for connecting the third connector to a common connection point.

4. The apparatus according to claim 3, wherein a resistor value R of the first, second and third resistors are defined by the equation R=Z/(n+1), wherein Z is the impedance for all transmitted signals and n is a frequency multiplication factor.

5. The apparatus according to claim 1, wherein the passive circuit is a network comprising a first transmission line being connected to the first connector and a second transmission line being connected to the second connector, wherein the transmission lines are arranged such that the output is achieved by a fly-by of the first and second signals.

6. The apparatus according to claim 1, wherein the passive circuit comprises a delay line for delaying the first signal or the second signal.

7. A signal generator, comprising:
an apparatus according to claim 1;
a first driver for providing the first signal; and
a second driver for providing the second signal.

8. The signal generator according to claim 7, further comprising a control unit being adapted to control the first and second drivers such that a timing of the first and second signals is such that the clock period of the output signal is a multiple of the frequency of the first and second signals.

9. The signal generator according to claim 8, wherein a multiplication factor, defining the relationship between the clock periods of the input signals and the clock period of the output signal is user-selectable.

10. The signal generator according to claim 9, wherein the control unit is configured to calculate the timing of the first and second signals dependent on the selected multiplication factor.

11. The signal generator according to claim 9, wherein the output signal is a digital signal and wherein the control unit is configured to place edges of the first and second signals such that the combination of the first and second signals provides the digital signal.

12. The signal generator according to claim 11, wherein the digital signal is a non-periodic signal and wherein a bandwidth of the digital signal is higher than a bandwidth of the first and second signals.

13. The signal generator according to claim 9, wherein the control unit is configured to calculate a voltage level of the first and second signals such that a voltage level of the output signal corresponds to a required voltage level at the device under test.

14. Method for generating an output signal having a higher frequency than a first signal received from a test equipment associated to a first channel and a second signal received from the test equipment associated to a second channel, comprising the steps of:
receiving the first signal on a first input;
receiving a second signal on a second input, wherein the first and second signals are phase shifted with respect to each other;
combining the signals received at said first and second input by using a passive circuit, into an output signal; and
providing the output signal to an output, adapted to be connected to a device under test.

15. The method according to claim 14, further comprising a step of determining timings of the first and second signals and a step of generating the first and second signals in accordance with the calculated timings.

16. The method according to claim 15, wherein the step of determining the timings depends on a multiplication factor, such that a duty cycle of the received signals is larger than half a clock period in case of an even multiplication factor and a duty cycle of the received signals is half the clock period in case of an odd multiplication factor.

17. The method according to claim 15, wherein the step of determining depends on the number n of signals to be combined, such that the phase of the signals is shifted by 1/n times the clock period.

18. The method according to claim 15, wherein the timing is determined such that half the signals plus 1 are at a high level for driving a high output signal and half the signals plus 1 are at a low level for driving a low output signal.

19. Usage of a passive circuit comprising a first input, a second input and an output, said output providing an output signal being a combination of input signals applied to the first and second input and having a higher frequency than the input signals for increasing the frequency of signals provided on a first and a second channel of a test equipment by connecting the first input to the first channel and the second input to the second channel.
